(19) United States
(12) Patent Application Publication
(10) Pub. No.: US 2026/0123305 A1
(43) Pub. Date: Apr. 30, 2026

(54) Methods for Substrate Bonding

(71) Applicant: Applied Materials, Inc., Santa Clara, CA (US)

(72) Inventors: Tyler SHERWOOD, Fonda, NY (US); Raghav SREENIVASAN, Santa Clara, CA (US); Mariia GORCHICHKO, San Jose, CA (US); Kun LI, Delmar, NY (US); Anh NGUYEN, Loudonville, NY (US); Joseph SHEPARD, Saratoga Springs, NY (US); Siddarth KRISHNAN, San Jose, CA (US); Michael CHUDZIK, Mountain View, CA (US)

(21) Appl. No.: 18/932,514

(22) Filed: Oct. 30, 2024

(51) Int. Cl. H01L 21/265; H01L 21/02; H01L 21/18; H01L 21/268; H01L 23/00

(52) U.S. Cl. CPC H10P 30/204; H10P 10/128; H10P 30/208; H10P 34/42; H10P 90/12; H10W 80/011; H10W 80/312; H10W 80/327

(57) ABSTRACT

Methods of processing a substrate are disclosed herein which include treating a surface of a first portion of the substrate to produce a treated substrate having a treated first portion and a second portion, wherein a bonding speed of the treated first portion to another substrate is different than a bonding speed of the second portion to the other substrate. A method of bonding a first substrate to a second substrate is also disclosed.

### FIELD

Embodiments of the present disclosure generally relate to the field of semiconductor manufacturing processes, more particularly, to methods to process substrates for bonding, and bonding of the processed substrates.

### BACKGROUND

Advanced packaging technologies involving substrate bonding such as wafer to wafer bonding has become prevalent in the heterogeneous integration front. Wafer deformation and bond strength are two of the biggest challenges for the current wafer to wafer bonding technologies, which include fusion bonding of activated dielectric substrates and hybrid bonding in which the bonding of the substrates result in the formation of metal-to-metal contacts.

However, the inventors have observed that internal and external strains resultant from bonding of substrates may result in deformation induced by the wafer or other substrate bonding process, having a detrimental consequences on the final result. The bonding deformation can lead to a pattern distortion, preventing subsequent lithography, or which may result in overlay issues. Bonding deformation may also prevent an accurate device to device alignment.

Higher bond strength is typically desired for wafer-to-wafer bonding, including for multiple layer fusion bonding and pitch scaling hybrid bonding.

The inventors have observed that when wafer surfaces are not perfectly flat, adhesion forces can deform the material elastically. The quality of the adhesion obtained has been observed to depend on the material's elastic properties and the geometry of the material. These deformations may be on a macroscopic scale, e.g., cm, a microscopic scale, e.g., micrometers, or a nanoscopic scale, e.g., nanometers.

Accordingly, the inventors have provided an improved method for treating substrates for bonding, and methods of bonding substrates which addresses these and other issues.

### SUMMARY

Methods for processing substrates and methods for bonding the processed substrates are provided herein. In embodiments, a method of processing a substrate comprises treating a surface of a first portion of the substrate to produce a treated substrate having a treated first portion and a second portion, wherein a bonding speed of the treated first portion to another substrate is different than a bonding speed of the second portion to the other substrate.

In embodiments, a method of bonding a first substrate to a second substrate comprises treating a surface of a first portion of the first substrate to produce a treated first substrate having a treated first portion and a second portion, followed by contacting the surface of the treated first substrate with a surface of the second substrate under conditions sufficient to bond the treated first substrate with the second substrate; wherein a bonding speed of the treated first portion to the second substrate is greater than a bonding speed of the second portion of the treated substrate to the second substrate.

In embodiments, a non-transitory computer readable medium is provided, having instructions stored thereon which, when executed, causes a processing chamber to perform a method of processing a substrate, the method comprising treating a surface of a first portion of the substrate to produce a treated substrate having a treated first portion and a second portion, wherein a bonding speed of the treated first portion to another substrate is different than a bonding speed of the second portion to the other substrate.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 is a side view of two substrates being bonded together in accordance with embodiments of the present disclosure.

FIG. 2 is a diagram depicting a treated substrate according to embodiments disclosed herein.

FIG. 3 is a diagram depicting a treated substrate according to another embodiment disclosed herein.

FIG. 4 depicts a bonded pair of substrates in which the upper substrate is treated according to embodiments disclosed herein.

FIG. 5 depicts a bonded pair of substrates in which both the upper substrate and the lower substrate have been treated according to embodiments disclosed herein.

FIG. 6A depicts an upper substrate having features covered by a dielectric layer.

FIG. 6B depicts the upper substrate shown in FIG. 6A which has been treated by nitridation according to embodiments disclosed herein.

FIG. 6C depicts a lower substrate having features covered by a dielectric layer.

FIG. 6D depicts the lower substrate shown in FIG. 6C which has been treated by nitridation according to embodiments disclosed herein.

FIG. 6E depicts the upper treated substrate shown in FIG. 6B bonded to the lower treated substrate shown in FIG. 6D.

FIG. 7A depicts an upper substrate having metallic features at a surface.

FIG. 7B depicts the upper substrate shown in FIG. 7A in which the dielectric portion of the substrate have been treated by nitridation according to embodiments disclosed herein.

FIG. 7C depicts a lower substrate having metallic features at a surface.

FIG. 7D depicts the lower substrate shown in FIG. 7C in which the dielectric portions of the substrate have been treated by nitridation according to embodiments disclosed herein.

FIG. 7E depicts the upper treated substrate shown in FIG. 7B hybrid bonded to the lower treated substrate shown in FIG. 7D, wherein metal-to-metal contact is made between the upper and lower substrates according to embodiments disclosed herein.

FIG. 8 depicts a tool suitable to perform the method to produce a treated substrate according to embodiments disclosed herein.

FIG. 9 depicts a UV treatment chamber suitable to perform the method to produce a treated substrate according to embodiments disclosed herein.

FIG. 10 depicts a method of processing a substrate in accordance with embodiments of the present disclosure.

FIG. 11 depicts a method of bonding a first substrate to a second substrate in accordance with embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

For purposes of the present disclosure, unless indicated otherwise, the terms “substrate” and “wafer” are referred to interchangeably.

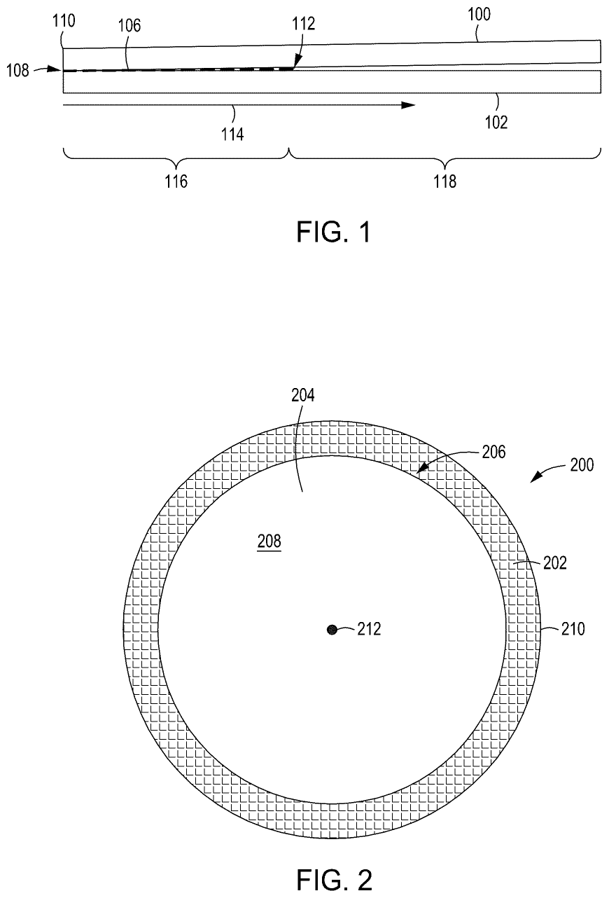

The inventors have observed that direct wafer to wafer bonding proceeds according to a sequence of events. The actual bonding process may be described by four different events. As depicted in FIG. 1, first, before initiation of the bonding, the top wafer 100 is positioned and then released to slowly contact the bottom wafer 102. During initiation of the bonding, an external force is applied to at least one point on the top wafer 100, bringing the top wafer 100 and the bottom wafer 102 into contact and initiating the bonding, indicated by dashed line 106. The point of the top wafer 100 to which the external force is applied is referred to as the initiation point 108. In embodiments, the initiation point 108 may be located at or proximate to an outer edge 110 of the top wafer 100, a middle or center of the wafer, or anywhere in between. In embodiments, the external force may be gravity or an applied force which presses the top wafer 100 and the bottom wafer 102 together.

Second, a contact event follows, wherein contact occurs between the top wafer 100 and the bottom wafer 102 while the external force is maintained. Thirdly, the contact event is followed by a propagation event, wherein a bonding front 112 forms and then propagates (arrow 114) across the entire wafer surface at a bonding speed. The bonding speed is determined as the distance the bonding front 112 travels across the top wafer 100 and the bottom wafer 102 divided by time, e.g., micrometers per second or millimeters per second, depending on the size of the substrate. The bonding speed may be determined linearly or as an angular velocity (e.g., radians per second), depending on the arrangement of the two surfaces being bonded together.

During the propagation event, the surface of the top wafer 100 and the bottom wafer 102 combined is divided at the bonding front 112 into an ever-increasing bonded area or portion 116, and a decreasing non-bonded area or portion 118.

Subsequent curvature of two bonded wafers may be influenced by the initiation event. The initiation event may result in a uniform curvature of the two bonded wafers due to various bonding dynamics. For example, wafer deflection from center to edge, wherein the initiation point is proximate to a center of the wafer, may produce different results than an initiation point located on an edge to produce a bonding front moving from edge to edge of the substrates.

The effect of the initiation event on the resultant bonded wafers has been observed to by influenced by the time needed for a gap height between the two wafers to become smaller than 100 nm, which is the molecular mean free path in air at ambient pressure. Below the 100 nm gap, adhesion contact is expected to occur.

A small positive curvature has been observed to increase considerably with the time needed for spontaneous initiation to occur. Without wishing to be bound by theory, the inventors believe that intrinsic curvature balances the induced curvature. Hence, the wafer becomes almost flat when approaching the bottom surface. On the other hand, a large negative or positive curvature decreases the spontaneous initiation lime.

The inventors have further observed that in the case of a positive curvature, the contact area is not the center of the wafer, but a ring around the wafer center, even for a large curvature. Thus, an air bubble between the two wafers may remain trapped in a central region of the bonded wafers.

The propagation event may also influence wafer curvature. The inventors have observed that wafer curvature has at least two contributions due to bond wave propagation. These include the energy balance with the work of adhesion causing a change in the wafer profile during the propagation, along with fluid flow and the viscous dissipation dynamics. In embodiments, the energy balance is modified by treatment of the wafer, which may result in either positive or negative curvature. The viscous dissipation of any interlaying gas present at the bonding front has been observed to increase for negative curvature and decrease for positive curvature.

In embodiments, a method of processing a substrate comprises treating a surface of a first portion of the substrate to produce a treated substrate having a treated first portion and a second portion, wherein a bonding speed of the treated first portion to another substrate is different than a bonding speed of the second portion to the other substrate. In embodiments, the treated first portion is proximate to an outer edge of the treated substrate, and the second portion is proximate to a center of the treated substrate, and wherein a bonding speed of the treated first portion to the other substrate is faster than the bonding speed of the second portion to the other substrate.

In other embodiments, the second portion is proximate to an outer edge of the treated substrate, and the treated first portion is proximate to a center of the treated substrate, and wherein a bonding speed of the treated first portion to the other substrate is faster than the bonding speed of the second portion to the other substrate.

In embodiments, the treating of the first portion comprises infusing and/or implanting argon, oxygen, hydrogen, and/or nitrogen. In embodiments, the treating of the first portion comprises infusion, implantation, plasma assisted implantation, decoupled plasma implantation, low power pulsed plasma implantation, or a combination thereof, of the surface of the first portion using argon, oxygen, hydrogen, nitrogen, and/or the like.

In embodiments, the implantation into a dielectric of the first portion is to a depth of less than or equal to about 10 nm. In embodiments, the treated first portion has a higher concentration of Si—ON, —Si—N, and/or AlOₓN moieties relative to the second portion of the treated substrate. In embodiments, the treating of the first portion comprises plasma nitridation, decoupled plasma nitridation, and/or low power pulsed plasma nitridation of the surface of the first portion. In embodiments, the treating of the first portion comprises flowing a first flow rate of nitrogen gas into a decoupled plasma nitridation processing chamber proximate to the first portion of the substrate which is different than a second flow rate of nitrogen gas flowing into the decoupled plasma nitridation processing chamber proximate to the second portion of the substrate.

In some embodiments, the treating of the first portion comprises contacting the first portion with UV radiation in the presence of NH₃ and/or an amine under conditions sufficient to increase a nitrogen concentration of the treated first portion relative to the second portion.

In embodiments, the treated substrate comprises an argon, oxygen, hydrogen, and/or nitrogen (i.e., implanted species) concentration gradient which increases radially from a center to an outer edge of the substrate.

In embodiments, the treated substrate comprises a plurality of concentric radial zones, wherein an average concentration of the implanted species in a first radial zone is different than an average concentration of the implanted species in a second radial zone. In some embodiments, the first radial zone is located proximate to an outer edge of the substrate and has a higher average nitrogen concentration than the second radial zone located adjacent to the first radial zone.

In embodiments a method of bonding a first substrate treated according to one or more embodiments disclosed herein to a second substrate, comprises treating a surface of a first portion of the first substrate to produce a treated first substrate having a treated first portion and a second portion, followed by contacting the surface of the treated first substrate with a surface of the second substrate under conditions sufficient to bond the treated first substrate with the second substrate; wherein a bonding speed of the treated first portion to the second substrate is greater than a bonding speed of the second portion of the treated substrate to the second substrate.

In some embodiments, the method further comprises treating a surface of a first portion of the second substrate according to one or more embodiments disclosed herein, to produce a treated second substrate having a treated first portion and a second portion, prior to contacting the surface of the treated first substrate with the treated second substrate.

In embodiments, the treated first portion is proximate to an outer edge of the treated first substrate, and the second portion is proximate to a center of the treated first substrate, and wherein a bonding speed of the treated first portion to the second substrate is faster than the bonding speed of the second portion to the second substrate. In embodiments, the treated first substrate comprises a uniform nitrogen concentration gradient which increases radially outward from a center to an outer edge of the treated substrate. In embodiments, the treated first substrate comprises a plurality of radial bands, each having an average nitrogen concentration, wherein an average nitrogen concentration of a first band is different from a second average nitrogen concentration of a second adjacent band.

FIG. 2 depicts a treated substrate 200 according to embodiments disclosed herein. A portion of a surface 206 of the substrate 204 is treated to form a treated portion 202 such that a bonding speed of the treated portion 202 to another substrate (see FIG. 1) is different than a bonding speed of the second portion 208 to the other substrate. In embodiments, the second portion 208 is not treated. In other embodiments, the second portion 208 is treated at another level of treatment and/or a different type of treatment such that a bonding speed of the treated portion 202 to another substrate is different than a bonding speed of the second portion 208 to the other substrate.

In the embodiment depicted in FIG. 2, the treated portion 202 is proximate to an outer edge 210 of the treated substrate, and the second portion 208 is proximate to a center 212 of the treated substrate 200.

In some embodiments, a bonding speed of the first treated portion 202 to the other substrate is faster than the bonding speed of the second portion 208 to the other substrate. In some embodiments, a bonding speed of the second portion 208 to the other substrate is faster than the bonding speed of the first treated portion 202 to the other substrate.

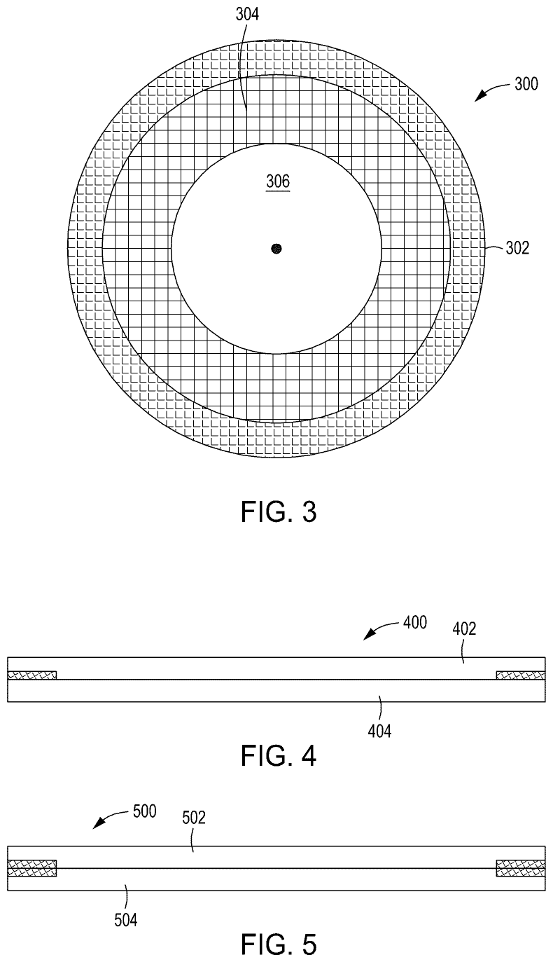

As depicted in FIG. 3, in embodiments, a treated substrate 300 comprises a plurality of different portions, e.g., of radial bands: a first radial band 302, a second radial band 304, and a center or third radial band 306 for a round substrate, each having an average nitrogen concentration, wherein an average nitrogen concentration of the first radial band 302 is different than the average nitrogen concentration of the second radial band 304, and the average nitrogen concentration of the second radial band 304 is different than the average nitrogen concentration of the third radial band 306. In some embodiments, the first radial band 302 adjacent to the second radial band 304. In other embodiments, the treating results in a gradual change in infusion from a center to the edge of the substrate.

FIG. 4 depicts a bonded pair of substrates 400 in which the upper substrate 402 is a treated substrate according to embodiments disclosed herein, and the lower substrate 404 (e.g., the other substrate) has not been treated according to embodiments disclosed herein.

FIG. 5 depicts a bonded pair of substrates 500 in which both the upper substrate 502 and the lower substrate 504 are treated substrates according to embodiments disclosed herein.

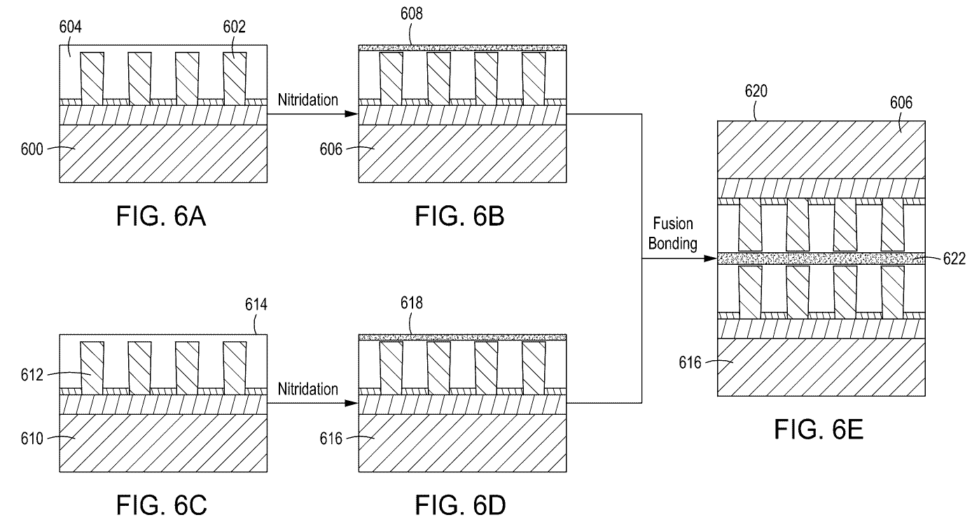

FIG. 6A depicts an upper substrate 600 having features 602 covered by dielectric layer 604. In embodiments, the features 602 may include one or more semiconductor devices, e.g., transistors and the like, formed on the substrate.

FIG. 6B depicts a treated upper substrate 606 having a treated portion 608 which has been treated by nitridation according to embodiments disclosed herein.

FIG. 6C depicts a lower substrate 610 having features 612 covered by dielectric layer 614. In embodiments, the features 612 may include one or more semiconductor devices, e.g., transistors and the like, formed on the substrate.

FIG. 6D depicts a treated lower substrate 616 having a treated portion 618 which has been treated by nitridation according to embodiments disclosed herein.

FIG. 6E depicts a pair of bonded treated substrates 620 in which the treated upper substrate 606 bonded to the treated lower substrate 616 through the bonded treated portions 608 and 618 forming a bonded layer of dielectric 622.

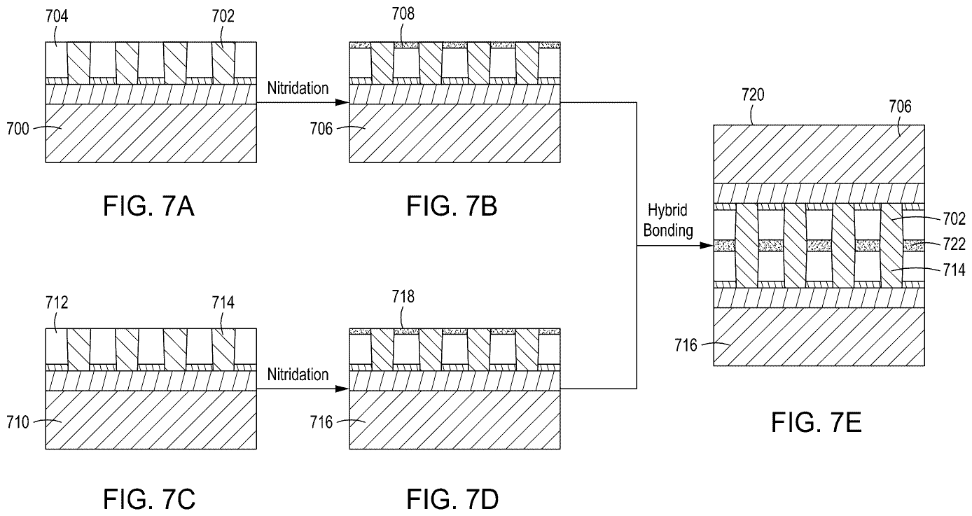

FIG. 7A depicts an upper substrate 700 having metallic features 702 at a surface disposed between dielectric portions 704.

FIG. 7B depicts a treated upper substrate 706 having treated portions 708 in which the dielectric portions 704 of the treated upper substrate 706 have been treated by nitridation according to embodiments disclosed herein.

FIG. 7C depicts a lower substrate 710 having metallic features 712 at a surface disposed between dielectric portions 714.

FIG. 7D depicts a treated lower substrate 716 having treated portions 718 in which the dielectric portions 714 of the treated substrate 716 have been treated by nitridation according to embodiments disclosed herein.

FIG. 7E depicts a pair of hybrid bonded treated substrates 720 in which the treated upper substrate 706 bonded to the treated lower substrate 716 through the bonded treated portions 708 and 718 forming a bonded layer 722 of dielectric as part of a hybrid bond in which metal-to-metal contact is made between the metal features 702 and 714.

In embodiments, treating of the surface of the substrate refers to “activation” of the portion of the substrate to increase bonding of the substrate to another substrate. In embodiments, the treating of the first portion comprises infusing and/or implanting nitrogen into a dielectric of the first portion to a depth of less than or equal to about 10 nm. In embodiments, the treated first portion has a higher concentration of Si—ON, —Si—N, and/or AlOₓN moieties relative to the second portion of the treated substrate.

In embodiments, the treating of the surface of the first portion comprises infusion, implantation, plasma assisted implantation, decoupled plasma implantation, low power pulsed plasma implantation, or a combination thereof, of the surface of the first portion using argon, oxygen, hydrogen, and/or nitrogen. In some embodiments, the treating of the first portion comprises plasma nitridation, decoupled plasma nitridation, and/or low power pulsed plasma nitridation of the surface of the first portion, wherein low power pulsed plasma conditions include a temperature range from about 25° C. up to about 500° C., a pressure from about 5 millitorr to 100 millitorr, an Rf power from about 100 W to 3000 W, and a relative gas flow from about 10% to 100%.

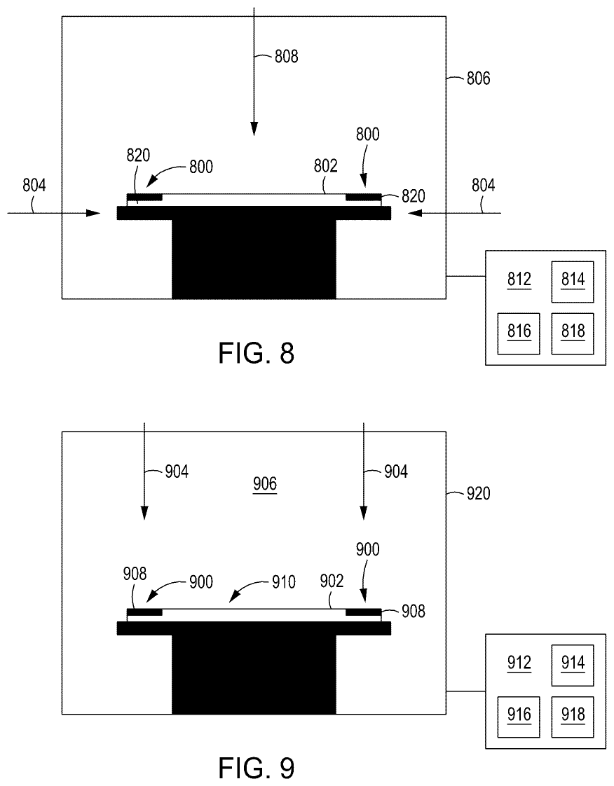

As depicted in FIG. 8, in embodiments, the treating of the first portion 800 of the substrate 802 comprises flowing a first flow rate 804 of nitrogen and/or ammonia gas, and/or a gas comprising an amine, into a plasma nitridation processing chamber 806 proximate to the first portion 800 of the substrate 802 which is different than a second flow rate 808 of nitrogen and/or ammonia gas flowing into the plasma nitridation processing chamber 806 proximate to the second portion 810 of the substrate 802 thereby forming a treated first portion 820 having an increased nitrogen concentration relative to the second portion 810.
In embodiments, the first flow rate 804 is proximate to the outer edge and is higher than the second flow rate.

In embodiments, the plasma nitridation processing chamber 806 may further include a controller 812 includes a central processing unit (CPU) 814, a memory 816, and a support circuit 818 utilized to control the process sequence and regulate the gas flows. The CPU 814 may be of any form of a general-purpose computer processor that may be used in an industrial setting. The software routines can be stored in the memory 816, such as random-access memory, read only memory, floppy, or hard disk drive, or other form of digital storage. The support circuit 818 is conventionally coupled to the CPU 814 and may include cache, clock circuits, input/output systems, power supplies, and the like. Bi-directional communications between the controller 812 and the various components of the plasma nitridation processing chamber 806 are handled through numerous signal cables, and the like.

In another embodiment, as depicted in FIG. 9, the substrate is treated in a UV treatment nitridation processing chamber 920 wherein the treating of the first portion 900 of the substrate 902 comprises contacting the first portion 900 with UV radiation 904 in the presence of a processing gas 906 comprising NH₃ and/or an amine, under conditions sufficient to form a treated first portion 908 having an increased nitrogen concentration relative to the second portion 910.

In embodiments, the UV treatment nitridation processing chamber 920 may further include a controller 912 having a central processing unit (CPU) 914, a memory 916, and a support circuit 918 utilized to control the process sequence and regulate the gas flows. The CPU 914 may be of any form of a general-purpose computer processor that may be used in an industrial setting. The software routines can be stored in the memory 916, such as random-access memory, read only memory, floppy, or hard disk drive, or other form of digital storage. The support circuit 918 is conventionally coupled to the CPU 914 and may include cache, clock circuits, input/output systems, power supplies, and the like. Bi-directional communications between the controller 912 and the various components of the UV treatment nitridation processing chamber 920 are handled through numerous signal cables, and the like.

In embodiments, the treated substrate comprises an implanted species e.g., nitrogen concentration gradient which increases radially from a center to an outer edge of the substrate. In embodiments, the increase in the implanted species, e.g., nitrogen concentration is uniform between the center and the outer edge of the substrate. In some embodiments, the increase in nitrogen concentration is linear. In some embodiments, the increase in nitrogen concentration is logarithmic.

In embodiments, the treated substrate comprises a plurality of concentric radial zones, wherein an average implanted species, e.g., nitrogen concentration of a first radial zone is different than an average nitrogen concentration of a second radial zone. In some of such embodiments, the increase in nitrogen or other implanted species concentration from zone to zone is stepwise.

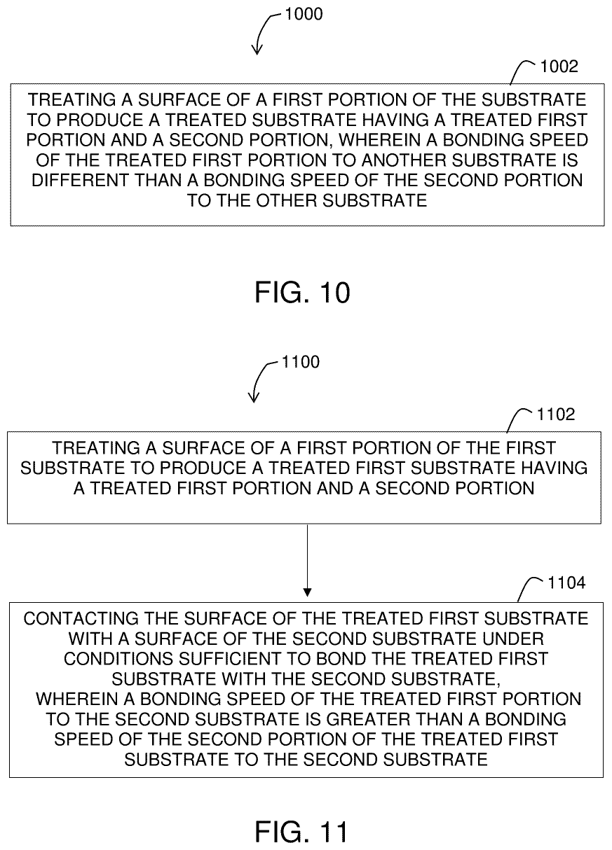

FIG. 10 is a flowchart depicting a method 1000 of processing a substrate according to embodiments disclosed herein. Method 1000 includes treating a surface of a first portion of the substrate to produce a treated substrate having a treated first portion and a second portion, wherein a bonding speed of the treated first portion to another substrate is different than a bonding speed of the second portion to the other substrate (block 1002). In embodiments, the method 1000 may include additional blocks. In embodiments, method 1000 may be performed, for example, in a suitable cluster tool and process chambers. Accordingly, in embodiments, a non-transitory computer readable medium, having instructions stored thereon which, when executed, cause a processing chamber to perform a method of processing a substrate according to one or more embodiments disclosed herein.

FIG. 11 is a flowchart depicting a method 1100 of processing a substrate according to embodiments disclosed herein. Method 1100 treating a surface of a first portion of the first substrate to produce a treated first substrate having a treated first portion and a second portion (block 1102), followed by contacting the surface of the treated first substrate with a surface of the second substrate under conditions sufficient to bond the treated first substrate with the second substrate; wherein a bonding speed of the treated first portion to the second substrate is greater than a bonding speed of the second portion of the treated first substrate to the second substrate (block 1104). In embodiments, the method 1100 may include additional blocks. In embodiments, method 1100 may be performed, for example, in a suitable cluster tool and process chambers. Accordingly, in embodiments, a non-transitory computer readable medium, having instructions stored thereon which, when executed, cause a processing chamber to perform a method of processing a substrate according to one or more embodiments disclosed herein.

### Embodiments

In accordance with embodiments of the disclosure, at least the following embodiments are contemplated.

E1. A method of processing a substrate, comprising:
treating a surface of a first portion of the substrate to produce a treated substrate having a treated first portion and a second portion, wherein a bonding speed of the treated first portion to another substrate is different than a bonding speed of the second portion to the other substrate.

E2. The method according to Embodiment E1, wherein the treated first portion is proximate to an outer edge of the treated substrate, and the second portion is proximate to a center of the treated substrate, and wherein a bonding speed of the treated first portion to the other substrate is faster than the bonding speed of the second portion to the other substrate.

E3. The method according to Embodiments E1-E2 wherein the treated first portion is proximate to a center of the treated substrate, and the second portion is proximate to an outer edge of the treated substrate, and wherein a bonding speed of the treated first portion to the other substrate is faster than the bonding speed of the second portion to the other substrate.

E4. The method according to Embodiments E1-E3, wherein the treating of the first portion comprises infusing and/or implanting argon, oxygen, hydrogen, and/or nitrogen into a dielectric of the first portion to a depth of less than or equal to about 10 nm.

E5. The method according to Embodiments E1-E4, wherein the treated first portion has a higher concentration of Si—ON, —Si—N, and/or AlOₓN moieties relative to the second portion of the treated substrate.

E6. The method according to Embodiments E1-E5, wherein the treating of the first portion comprises infusion, implantation, plasma assisted implantation, decoupled plasma implantation, low power pulsed plasma implantation, or a combination thereof, of the surface of the first portion using argon, oxygen, hydrogen, and/or nitrogen.

E7. The method according to Embodiment E6, wherein the treating of the first portion comprises flowing a first flow rate of nitrogen gas into a decoupled plasma nitridation processing chamber proximate to the first portion of the substrate which is different than a second flow rate of nitrogen gas flowing into the decoupled plasma nitridation processing chamber proximate to the second portion of the substrate.

E8. The method according to Embodiments E1-E7, wherein the treating of the first portion comprises contacting the first portion with UV radiation in the presence of NH₃ and/or an amine under conditions sufficient to increase a nitrogen concentration of the treated first portion relative to the second portion.

E9. The method according to Embodiments E1-E8, wherein the treated substrate comprises a concentration gradient of argon, oxygen, hydrogen, and/or nitrogen which increases radially from a center to an outer edge of the substrate.

E10. The method according to Embodiments E1-E9, wherein the treated substrate comprises a plurality of concentric radial zones, wherein an average argon, oxygen, hydrogen, and/or nitrogen concentration of a first radial zone is different than an average argon, oxygen, hydrogen, and/or nitrogen concentration of a second radial zone.

E11. The method according to Embodiment E10, wherein the first radial zone is located proximate to an outer edge of the substrate and has a higher average argon, oxygen, hydrogen, and/or nitrogen concentration than the second radial zone located adjacent to the first radial zone.

E12. A method of bonding a first substrate to a second substrate, comprising:
contacting the surface of a treated first substrate with a surface of the second substrate under conditions sufficient to bond the treated first substrate with the second substrate;
wherein the treated first substrate, the treated second substrate, or both are processed according to one or more of Embodiments E1-E11.

E13. A method of bonding a first substrate to a second substrate, comprising:
treating a surface of a first portion of the first substrate to produce a treated first substrate having a treated first portion and a second portion, followed by
contacting the surface of the treated first substrate with a surface of the second substrate under conditions sufficient to bond the treated first substrate with the second substrate;
wherein a bonding speed of the treated first portion to the second substrate is greater than a bonding speed of the second portion of the treated substrate to the second substrate.

E14. The method according to Embodiments E12-E13, further comprising treating a surface of a first portion of the second substrate to produce a treated second substrate having a treated first portion and a second portion, prior to contacting the surface of the treated first substrate with the treated second substrate.

E15. The method according to Embodiments E12-E14, wherein the treating the surface of the first portion comprises infusing and/or implanting argon, oxygen, hydrogen, and/or nitrogen into a dielectric of the first portion to a depth of less than or equal to about 10 nm.

E16. The method according to Embodiments E12-E15, wherein the treating of the surface of the first portion comprises infusion, implantation, plasma assisted implantation, decoupled plasma implantation, low power pulsed plasma implantation, or a combination thereof, of the surface of the first portion using argon, oxygen, hydrogen, and/or nitrogen.

E17. The method according to Embodiments E12-E16, wherein the treating of surface of the first portion comprises contacting the first portion of the first substrate with UV radiation in the presence of NH₃ under conditions sufficient to increase a concentration of Si—NH moieties in the first portion of the substrate relative to the second portion of the first substrate.

E18. The method according to Embodiments E12-E17, wherein the treated first portion is proximate to an outer edge of the treated first substrate, and the second portion is proximate to a center of the treated first substrate, and wherein a bonding speed of the treated first portion to the second substrate is faster than the bonding speed of the second portion to the second substrate.

E19. The method according to Embodiments E12-E18, wherein the treated first substrate comprises a uniform argon, oxygen, hydrogen, and/or nitrogen concentration gradient which increases radially outward from a center to an outer edge of the treated first substrate.

E20. The method according to Embodiments E12-E19, wherein the treated first substrate comprises a plurality of radial bands, each having an average argon, oxygen, hydrogen, and/or nitrogen concentration, wherein an average argon, oxygen, hydrogen, and/or nitrogen concentration of a first band is different from a second average argon, oxygen, hydrogen, and/or nitrogen concentration of a second adjacent band.

E21. A non-transitory computer readable medium, having instructions stored thereon which, when executed, cause a processing chamber to perform a method of processing a substrate according to one or more of Embodiments E1-E20.

The disclosure may be practiced using other semiconductor substrate processing systems wherein the processing parameters may be adjusted to achieve acceptable characteristics by those skilled in the art by utilizing the teachings disclosed herein without departing from the spirit of the disclosure. While the foregoing is directed to embodiments of the present disclosure, other and further embodiments of the disclosure may be devised without departing from the basic scope thereof.

1. A method of processing a substrate, comprising:
treating a surface of a first portion of the substrate to produce a treated substrate having a treated first portion and a second portion, wherein a bonding speed of the treated first portion to another substrate is different than a bonding speed of the second portion to the other substrate.

2. The method of claim 1, wherein the treated first portion is proximate to an outer edge of the treated substrate, and the second portion is proximate to a center of the treated substrate, and wherein a bonding speed of the treated first portion to the other substrate is faster than the bonding speed of the second portion to the other substrate.

3. The method of claim 1, wherein the treated first portion is proximate to a center of the treated substrate, and the second portion is proximate to an outer edge of the treated substrate, and wherein a bonding speed of the treated first portion to the other substrate is faster than the bonding speed of the second portion to the other

4. The method of claim 1, wherein the treating of the surface of the first portion of the substrate comprises infusing and/or implanting argon, oxygen, hydrogen, and/or nitrogen into a dielectric bonding layer to a depth of less than or equal to about 10 nm.

5. The method of claim 1, wherein the treated first portion has a higher concentration of Si—ON, —Si—N, and/or AlOₓN moieties relative to the second portion of the treated substrate.

6. The method of claim 1, wherein the treating of the surface of the first portion of the substrate comprises infusion, implantation, plasma assisted implantation, decoupled plasma implantation, low power pulsed plasma implantation, or a combination thereof, using argon, oxygen, hydrogen, and/or nitrogen.

7. The method of claim 6, wherein the treating of the first portion comprises flowing a first flow rate of nitrogen gas into a decoupled plasma nitridation processing chamber proximate to the first portion of the substrate which is different than a second flow rate of nitrogen gas flowing into the decoupled plasma nitridation processing chamber proximate to the second portion of the substrate.

8. The method of claim 1, wherein the treating of the first portion comprises contacting the first portion with UV radiation in a presence of NH₃ and/or an amine under conditions sufficient to increase a nitrogen concentration of the treated first portion relative to the second portion.

9. The method of claim 1, wherein the treated substrate comprises a concentration gradient of argon, oxygen, hydrogen, and/or nitrogen which increases radially from a center to an outer edge of the substrate.

10. The method of claim 1, wherein the treated substrate comprises a plurality of concentric radial zones, wherein an average argon, oxygen, hydrogen, and/or nitrogen concentration of a first radial zone is different than an average argon, oxygen, hydrogen, and/or nitrogen concentration of a second radial zone.

11. The method of claim 10, wherein the first radial zone is located proximate to an outer edge of the substrate and has a higher average argon, oxygen, hydrogen, and/or nitrogen concentration than the second radial zone located adjacent to the first radial zone.

12. A method of bonding a first substrate to a second substrate, comprising:
treating a surface of a first portion of the first substrate to produce a treated first substrate having a treated first portion and a second portion, followed by
contacting the surface of the treated first substrate with a surface of the second substrate under conditions sufficient to bond the treated first substrate with the second substrate;
wherein a bonding speed of the treated first portion to the second substrate is greater than a bonding speed of the second portion of the treated first substrate to the second substrate.

13. The method of claim 12, further comprising treating a surface of a first portion of the second substrate to produce a treated second substrate having a treated first portion and a second portion, prior to contacting the surface of the treated first substrate with the treated second substrate.

14. The method of claim 12, wherein the treating the surface of the first portion comprises infusing and/or implanting argon, oxygen, hydrogen, and/or nitrogen into a dielectric of the first portion to a depth of less than or equal to about 10 nm.

15. The method of claim 12, wherein the treating of the surface of the first portion comprises infusion, implantation, plasma assisted implantation, decoupled plasma implantation, low power pulsed plasma implantation, or a combination thereof, of the surface of the first portion using argon, oxygen, hydrogen, and/or nitrogen.

16. The method of claim 12, wherein the treating of the surface of the first portion comprises contacting the first portion of the first substrate with UV radiation in a presence of NH₃ under conditions sufficient to increase a concentration of Si—NH moieties in the first portion of the substrate relative to the second portion of the first substrate.

17. The method of claim 12, wherein the treated first portion is proximate to an outer edge of the treated first substrate, and the second portion is proximate to a center of the treated first substrate, and wherein a bonding speed of the treated first portion to the second substrate is faster than the bonding speed of the second portion to the second substrate.

18. The method of claim 12, wherein the treated first substrate comprises a uniform argon, oxygen, hydrogen, and/or nitrogen concentration gradient which increases radially outward from a center to an outer edge of the treated first substrate.

19. The method of claim 12, wherein the treated first substrate comprises a plurality of radial bands, each having an average argon, oxygen, hydrogen, and/or nitrogen concentration, wherein an average argon, oxygen, hydrogen, and/or nitrogen concentration of a first band is different from a second average argon, oxygen, hydrogen, and/or nitrogen concentration of a second adjacent band.

20. A non-transitory computer readable medium, having instructions stored thereon which, when executed, cause a processing chamber to perform a method of processing a substrate, the method comprising:
treating a surface of a first portion of the substrate to produce a treated substrate having a treated first portion and a second portion, wherein a bonding speed of the treated first portion to another substrate is different than a bonding speed of the second portion to the other substrate.
